(19) United States
(12) Patent Application Publication
(10) Pub. No.: US 2003/0034065 A1
(43) Pub. Date: Feb. 20, 2003

(54) Method and device for selectively emitting photons

(75) Inventor: Andrew Meulenberg JR., Bedford, MA (US)

Correspondence Address: TESTA, HURWITZ & THIBEAULT, LLP, HIGH STREET TOWER, 125 HIGH STREET, BOSTON, MA, 02110, US

(73) Assignee: The Charles Stark Draper Laboratory, Inc., Cambridge, MA

(21) Appl. No.: 10/219,049

(22) Filed: Aug. 14, 2002

Related U.S. Application Data
(60) Provisional application No. 60/312,198, filed on Aug. 14, 2001.

(51) Int. Cl. H01L 31/00

(52) U.S. Cl. 136/253

(57) ABSTRACT

A selective emitter for a thermophotovoltaic system includes a heat source and a semiconductor layer having a thickness less than about 10 microns in thermal communication with the heat source. The heat source provides thermal energy to the semiconductor layer, which emits photons having a selected wavelength that is suitable for conversion into electrical energy by a thermophotovoltaic converter, in response to receiving thermal energy.

### REFERENCE TO RELATED APPLICATIONS

This application claims the benefit of U.S. Provisional Patent Application Serial No. 60/312,198, filed on Aug. 14, 2001, and entitled “Method And Device For Selectively Emitting Photons,” the entire contents of which are incorporated by reference herein.

### FIELD OF THE INVENTION

The invention relates to devices and methods for selectively emitting photons. In particular, in one embodiment, the invention relates to combining a semiconductor layer with a heat source for converting thermally excited electronic motion into photons of a selective wavelength.

### BACKGROUND OF THE INVENTION

Thermophotovoltaic (TPV) converters convert photons to electrical energy. Generally, a TPV system includes a heat source, an emitter, and a converter. The emitter, through physical (or radiant) contact with the heat source, is heated and then converts thermally excited electrons into photons. These photons are then transmitted to, and converted into electrical energy via, the converter. The efficiency of the converter depends upon its spectral response to the wavelength of the photons, and the spectrum of these wavelengths emitted by the emitter. Generally, photons having too long a wavelength cannot be converted into electrical energy and can produce unwanted heat in the converter, thereby reducing the overall conversion efficiency of input heat into output electricity. Photons with too short a wavelength generate electricity in the converter, but these short wavelength photons also generate excess energy that is converted into heat inside the converter and thus lower conversion efficiency.

Conventional methods of selective emission of photons utilize specific materials to alter the blackbody (BB) radiation spectrum from a ‘hot’ source. Some selective emitters, such as rare-earth-oxide emitters, enhance the output of useful radiation by the incorporation of specific elements into an optically transparent ceramic. These emitters collect thermal energy from adjacent (compatible) atoms of the ceramic and subsequently release this energy via photons having a selected wavelength range. The use of quantum “dots” on the surface of the source, to provide selective emission, has also been proposed. In addition, metals that have selective emission as a result of their wavelength-dependent refractive indices have also been suggested as possible selective emitters.

Other conventional approaches to this problem include use of selective filters (multilayer or “antenna”) to remove non-useful (generally long-wavelength) light from an emitted blackbody (or selective emitter) spectrum. These filters are generally thermally isolated from the source and, in the most efficient implementations, provide broadband reflective surfaces to return the long-wavelength light to the emitter.

As discussed above, the conversion efficiency of prior art TPV systems is poor because of the high percentage of substantially unusable light present in the emitter spectrum. Currently, conventional selective emitters require the close proximity of selected materials to the heat source for efficient transfer of thermal energy prior to emission of the selected-wavelength photons.

One measure of the conversion efficiency of a TPV system is the selectivity ratio of the emitter. The selectivity ratio is defined as the average emissivity (ελ) of a photon having a wavelength suitable for generating maximum electricity in the converter (e.g., λ=1.5 microns) to the average emissivity of a photon having a wavelength that is not suitable for generating electricity (e.g., λ=5 microns). Most rare-earth oxide and dielectric selective emitters have a selectivity ratio that is typically no greater than 3. The selectivity ratio for these emitters is dependent on the thickness of the selective emitter and, for thin emitters, on the reflectance of the metal backing used as a substrate. The selectivity ratio is also limited by the properties of any selective filters used and by the optical-line structure (thermally broadened) of the selective emitter. This line structure means that, for several wavelengths, the spectral emittance is at the maximum value which is less than 1; but, for much of the spectral band, the emittance is significantly lower than the maximum value. Thus, the average emittance within a useable band is significantly less than the maximum. Increasing the emitter thickness can increase average emittance, however, the increased thickness may also increase the unwanted long-wavelength emittance more than the desired emittance. As a result, the selectivity ratio is actually decreased. In addition, increasing emitter thickness also increases the temperature gradient across the emitter, thereby lowering the emitter surface temperature and thus the total emittance.

Metallic selective emitters typically have an increased emissivity at lower wavelengths. The selectivity ratio can be as high as about 4.3 and metallic selective emitters typically do not have the thickness problem of dielectric or rare-earth oxide selective emitters. The result of using this type emitter is to decrease the effective blackbody peak wavelength by about 0.5 microns, thus increasing the effective temperature and efficiency of the emitter. However, while metallic selective emitters (in terms of selectivity) are better than many other selective emitters, the metallic selective emitters still have a maximum emissivity in the useful wavelengths of only about ε_{λ}=0.3. The low emittance of metals is a result of their high reflectance, because the emittance is proportional to the absorptance of a material. Absorptance measures the amount of light disappearing at a single reflection (absorptance=absorption−reflection). Thus, while metals are highly absorbing, they may also be highly reflecting. As a result, metallic emittance is generally low. Despite the selectivity ratio, long-wavelength light over a large range reduces prior art TPV system efficiency. However, in combination with bandpass (selective) filters, useful metallic-emitter efficiencies may be reached.

Selective filters, however, have disadvantages. Selective filters formed from multilayer films only eliminate narrow bands (generally about 2 microns) of unwanted wavelength. Thus, while the selective filters are helpful in removing some of the photons having a wavelength not suitable for generating electricity in the converter, they are not as useful as could be desired, particularly for low-temperature-emitter sources.

Alternatively, antenna filters may be used in TPV systems to transmit light for conversion into electricity. Antenna filters, however, are expensive and they still transmit a significant portion of the unwanted long-wavelength light and block useful light.

### SUMMARY OF INVENTION

In one embodiment, the invention is directed to a selective emitter for a thermophotovoltaic system. The selective emitter includes a heat source and a semiconductor layer in thermal communication with the heat source; the semiconductor layer of the selective emitter having a thickness less than about 100 microns. In some embodiments, the semiconductor layer includes at least one indirect bandgap semiconductor material, such as silicon, germanium, or a silicon germanium alloy. In other embodiments, the semiconductor layer includes direct bandgap semiconductor material, such as indium gallium arsenide or gallium arsenide. According to one feature, the semiconductor layer, when thermally activated, converts energy predominantly to photons having a wavelength within a range of about 1.2 microns to about 1.5 microns. In other embodiments, the semiconductor layer converts thermal energy into photons having other wavelength ranges, such as, for example, a range of about 1.5 microns to about 2 microns or about 2 microns to about 2.4 microns.

In some embodiments, the semiconductor layer is crystalline. Alternatively, in other embodiments the semiconductor layer is amorphous. Amorphous semiconductors may not have a forbidden band, and thus do not have a bandgap. Nevertheless, amorphous semiconductors have a refractive index that is equal to, or higher than, that of the crystalline semiconductors. In some embodiments, the semiconductor layer includes a multi-bandgap semiconductor material and in other embodiments the semiconductor layer includes at least two different semiconductor materials with different bandgaps. In one embodiment, the semiconductor layer may include an ungraded, graded, or stepped-bandgap semiconductor material.

In some embodiments, the selective emitter further includes at least one backing layer located between the heat source and the semiconductor layer. The backing layer is configured to increase output of photons of a wavelength suitable for conversion into electric energy by a photovoltaic converter relative to output of photons of a non-suitable wavelength. According to further embodiments, the backing layer includes a dielectric material, a metallic material, or a combination of one or more dielectric layers, one or more semiconductor layers, and one or more metallic layers.

In one embodiment, the invention is directed to a method for converting thermal energy into photons having a wavelength within a selected range. The method includes placing a semiconductor layer in thermal communication with a heat source; the semiconductor layer having a thickness less than about 100 microns. According to one feature, the method further includes optimizing (increasing output of photons of a wavelength suitable for conversion into electric energy by a photovoltaic converter relative to output of photons of a non-suitable wavelength) emission of photons by depositing an antireflective coating on the semiconductor layer. According to another feature, the method includes increasing emission of photons by depositing one or more backing layers on the semiconductor layer. In one embodiment, the one or more backing layers are located between the heat source and the semiconductor layer.

In one embodiment, the invention is directed to a method for converting thermal energy into electric energy. The method includes placing a semiconductor layer having a thickness less than about 100 microns in thermal communication with a heat source to generate photons having a wavelength within a selected wavelength range and collecting the photons within a photovoltaic converter configured to convert the photons into electric energy.

In another embodiment, the invention is directed to a selective emitter for a thermophotovoltaic system. The selective emitter includes a heat source and a composite layer in thermal communication with the heat source. The composite layer of the selective emitter has at least one quantum well for emitting photons and has a thickness less than about 10 microns. In some embodiments, the quantum well exists within undoped semiconductor materials. In other embodiments, the quantum well is an oriented crystal quantum well. Alternatively, the quantum well may be a non-planar quantum well or a stressed quantum well.

In some embodiments, the quantum well includes a metal confined within barriers formed by at least one of a metal material, a semiconductor material, and a dielectric material. In other embodiments, the work function of the metal itself may comprise a barrier sufficient to confine the quantum well, such as, for example, a metal-air interface or a metal-vacuum interface. In other embodiments, the quantum well exists within a composite layer including a region of a wide-bandgap material surrounding a region of a narrow bandgap material. In other embodiments, the composite layer further includes a dielectric material, such as sapphire (alumina).

The selective emitter may include a single or multilayer antireflective coating deposited on the composite layer. In addition, in some embodiments, the selective emitter includes at least one backing layer located between the heat source and the composite layer; the backing layer increasing output of photons of a wavelength suitable for conversion into electric energy by a photovoltaic converter. In some embodiments, the backing layer includes a dielectric material. In other embodiments, the backing layer includes a metallic material. In other embodiments, the backing layer includes a combination of one or more dielectric layers and one or more metallic layers.

In one embodiment, the invention is directed to a method for converting thermal energy into photons having a wavelength within a selected wavelength range. The method includes placing a composite layer, including at least one quantum well, in thermal communication with a heat source; the composite layer having a thickness less than about 10 microns. According to one feature, the method further includes increasing emission of photons by depositing a single or multilayer antireflective coating on the composite layer. According to another feature, the method includes increasing emission of photons by depositing one or more backing layers on the composite layer. The one or more backing layers are located between the heat source and the composite layer.

In one embodiment, the invention is directed to a method for converting thermal energy into electric energy. The method includes placing a composite layer, having a thickness less than 10 microns and including at least one quantum well in thermal communication with a heat source, and collecting photons (emitted from the composite layer) within a photovoltaic converter that converts the photons into electric energy.

### BRIEF DESCRIPTION OF DRAWINGS

The foregoing and other objects, features and advantages of the invention, as well as the invention itself, will be more fully understood from the following illustrative description, when read together with the accompanying drawings which are not necessarily to scale, and wherein:

FIG. 1 is a schematic view of a thermophotovoltaic system;

FIG. 2 is side view of an illustrative embodiment of a selective emitter including a heat source and a semiconductor layer according to the invention;

FIG. 3A is a side view of another illustrative embodiment of a selective emitter according to the invention;

FIG. 3B is a side view of another illustrative embodiment of a selective emitter according to the invention;

FIG. 4 is a side view of another illustrative embodiment of a selective emitter according to the invention;

FIG. 5A is a graph of modeled spectral power output data and emissivity data at 1400 K from a silicon semiconductor layer having a thickness of 0.33 microns and a tantalum backing layer according to an illustrative embodiment of the invention;

FIG. 5B is a graph of modeled spectral power output data and emissivity data at 1400 K from a silicon semiconductor layer having a thickness of 1 micron and a tantalum backing layer according to an illustrative embodiment of the invention;

FIG. 5C is a graph of modeled spectral power output data and emissivity data at 1400 K from a silicon semiconductor layer having a thickness of 6 microns and a tantalum backing layer according to an illustrative embodiment of the invention;

FIG. 5D is a graph of modeled spectral power output data and emissivity data at 1400 K from a silicon semiconductor layer having a thickness of 10 microns and a tantalum backing layer according to an illustrative embodiment of the invention;

FIG. 5E is a graph of modeled spectral power output data and emissivity data at 1400 K from a silicon semiconductor layer having a thickness of 100 microns and a tantalum backing layer according to an illustrative embodiment of the invention;

FIG. 5F is a graph of modeled spectral power output data and emissivity data at 1400 K from a silicon semiconductor layer having a thickness of 1000 microns and a tantalum backing layer according to an illustrative embodiment of the invention;

FIG. 6A is graph of modeled spectral output power data at 1400 K for a selective emitter including a silicon semiconductor layer having a thickness of 0.09 microns and having an optically-opaque and highly-conductive backing layer according to an illustrative embodiment of the invention;

FIG. 6B is graph of modeled spectral output power data at 1400 K for a selective emitter including a silicon semiconductor layer having a thickness of 0.6 microns and having an optically-opaque and highly-conductive backing layer according to an illustrative embodiment of the invention;

FIG. 7A is a graph of modeled spectral output power data at 1400 K for a neutral-spectral-density emitter having a thickness of 0.1 microns and having a backing layer including both a dielectric layer and a highly-conductive (e.g., greater than about 10⁶/ohm-m) metallic layer;

FIG. 7B is a graph of modeled spectral output power data at 1400 K for a selective emitter including a silicon semiconductor layer having a thickness of 0.1 microns and having a backing layer including both a dielectric layer and a highly-conductive (e.g., greater than about 10⁶/ohm-m) metallic layer according to an illustrative embodiment of the invention;

FIG. 8A is a graph of modeled spectral output power data and emissivity data at 1400 K for a neutral-spectral-density emitter having a thickness of 10 microns and an optically opaque and highly-conductive (e.g., greater than about 10⁶/ohm-m) backing layer;

FIG. 8B is a graph of modeled spectral output power data and emissivity data at 1400 K for a silicon semiconductor layer having a thickness of 10 microns and an optically-opaque and highly-conductive (e.g., greater than about 10⁶/ohm-m) backing layer according to an illustrative embodiment;

FIG. 9A is a graph of modeled spectral output power data at 1400 K for a silicon semiconductor layer having a thickness of 0.2 microns and also having a backing layer consisting of a dielectric material 0.2 microns thick according to an illustrative embodiment of the invention;

FIG. 9B is a graph of modeled spectral output power data at 1400 K for a silicon semiconductor layer having a thickness of 0.2 microns and having a backing layer consisting of a dielectric material 0.4 microns thick according to an illustrative embodiment of the invention;

FIG. 9C is a graph of modeled spectral output power data at 1400 K for a silicon semiconductor layer having a thickness of 0.2 microns and also having a backing layer consisting of a dielectric material 0.6 microns thick according to an illustrative embodiment of the invention;

FIG. 10A is a graph of modeled spectral output power data at 1400 K for a silicon semiconductor layer having a thickness of 0.1 microns and having a conductive backing layer with a conductivity of 2×10⁶/ohm-m according to an illustrative embodiment of the invention;

FIG. 10B is a graph of modeled spectral output power data at 1400 K for a silicon semiconductor layer having a thickness of 0.1 microns and having a conductive backing layer with a conductivity of 9×10⁶/ohm-m according to an illustrative embodiment of the invention;

FIG. 11A is a graph of modeled spectral output power data and emissivity data at 1400 K for a silicon semiconductor layer having a thickness of 10 microns and having a tantalum backing layer and an antireflective coating layer 0.1 microns thick according to an illustrative embodiment of the invention;

FIG. 11B is a graph of modeled spectral output power data and emissivity data at 1400 K for a silicon semiconductor layer having a thickness of 10 microns and having a tantalum backing layer and an antireflective coating of 0.2 microns thick according to an illustrative embodiment of the invention;

FIG. 11C is a graph of modeled spectral output power data and emissivity data at 1400 K for a silicon semiconductor layer having a thickness of 10 microns and having a tantalum backing layer and an antireflective coating of 0.3 microns thick according to an illustrative embodiment of the invention;

FIG. 12 is side view of an illustrative selective emitter including a heat source and a composite layer having at least one quantum well according to an illustrative embodiment of the invention;

FIG. 13 is an illustrative embodiment of the composite layer including a graded indium-gallium-arsenide and gallium-arsenide structure according to an illustrative embodiment of the invention; and

FIG. 14 is a side view of another embodiment of a selective emitter according to an illustrative embodiment of the invention.

### DETAILED DESCRIPTION OF ILLUSTRATIVE EMBODIMENTS

Thermophotovoltaic (TPV) systems convert thermal energy to electric energy. As shown in FIG. 1, a TPV system typically includes a heat source 2, an emitter 4 in thermal communication with the heat source 2, and a photovoltaic converter 8. The heat source 2 provides thermal energy to the emitter 4, which emits photons 6 in response. The photovoltaic converter 8 collects and converts some of these photons 6 into electric energy 10.

The invention, in one embodiment, is directed to emitters for TPV systems. An emitter, according to the present invention, emits photons having a selected wavelength that is suitable for conversion into electrical energy by a photovoltaic converter 8 (e.g., a wavelength within a wavelength range, such as from about 1.2 microns to about 1.5 microns, or from about 1.5 microns to about 2 microns). In general, the emitter of the invention includes a thin layer of a semiconductor material in physical or radiant contact with a heat source. Depending on application and/or the particular photoelectric converter being used, the thickness of the thin layer of semiconductor material ranges, illustratively, from about 0.005 microns to about 100 microns. In some particular examples, the thickness of the thin layer of semiconductor material may be, for example, less than 100 microns, less than 75 microns, less than 50 microns, less than 25 microns, less than 10 microns, less than 1 micron, less than 0.1 micron, or less than 0.01 micron.

Referring to FIG. 2, a selective emitter 15 according to one illustrative embodiment of the invention includes a heat source 18 and a semiconductor layer 20. The semiconductor layer 20 is in thermal communication with the heat source 18 (through either physical or radiant contact with the heat source 18) and converts thermally excited electrons into photons.

The semiconductor layer 20 can be either crystalline or amorphous and may include an indirect bandgap semiconductor material, such as, for example, silicon, germanium, or a silicon germanium alloy, or a direct bandgap semiconductor material, such as, for example, indium gallium arsenide, or gallium arsenide. The semiconductor layer may be doped (e.g., n or p doped, counter-doped, or differentially doped), but is preferably undoped. In other embodiments, the semiconductor layer 20 includes multi-bandgap semiconductor materials having a narrow (e.g., about 0.2 eV, or less) conduction band to suppress free-carrier emission. In other embodiments, the semiconductor layer 20 also includes two or more different semiconductor materials with different bandgaps. In some illustrative embodiments, the two or more semiconductor materials within the semiconductor layer 20 are deposited as multiple layers to produce a graded bandgap semiconductor layer. In other illustrative embodiments, the two or more semiconductor materials are deposited as single, distinct layers, thereby producing an ungraded bandgap semiconductor layer. In another illustrative embodiment, the semiconductor layer 20 includes a region of graded bandgap semiconductor materials and a region of ungraded bandgap semiconductor materials.

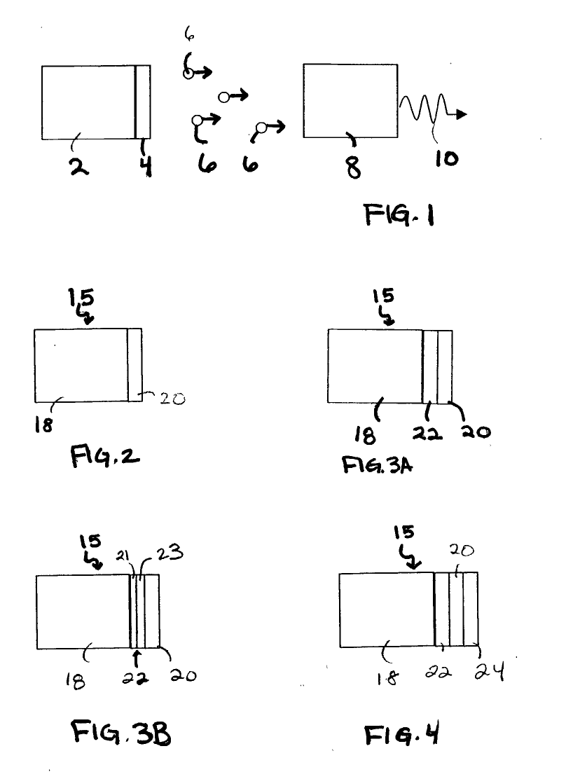

Referring to FIGS. 3A-3B, the illustrative selective emitter 15 includes one or more backing layers 22 located between the heat source 18 and the semiconductor layer 20. In the embodiment shown in FIG. 3A, the backing layer 22 is a single layer formed from one of a dielectric material, a semiconductor material, or a metallic material. In the embodiment shown in FIG. 3B, the backing layer 22 includes a metallic backing layer 21 and a dielectric backing layer 23. The backing layer 22, in some embodiments, provides structural integrity, better heat absorption or transfer properties, and/or increase selectivity efficiency of the wavelength selective emitter 15.

Since the semiconductor layer 20 is less than about 100 microns, almost all light emitted within the semiconductor layer 20 or the backing layer 22 passes therethrough. To prevent emittance from the backing layer 22 from dominating the emittance of the semiconductor layer 20, the material properties and thicknesses of the backing layer 22 is carefully tailored to reduce emittance from the backing layer 22. Materials within the backing layer 22 preferably have low absorptance (e.g., an absorptance less than about 1/cm) and/or high reflectance (e.g., a reflectance greater than about 0.9) for low emittance (e.g., emittance less than about 0.1). A combination of layers with these properties is preferred and may be achieved by including a layer of a transparent dielectric material (for example, a low absorptance material having a low refractive index of less than about 1.5) and a layer of a metal material (for example, a high reflectance material having a refractive index between about 0.5 and about 10). This combination of layers enables total internal reflectance to reflect back selected wavelengths from the semiconductor layer, thereby enhancing performance of the selective emitter 15. In another embodiment, the backing layer 22 includes at least one dielectric material layer (for example, having a refractive index of less than about 1.5), at least one semiconductor material layer (for example, having a refractive index within a range of about 3 to about 4), and at least one metal material layer (for example, having a refractive index within a range of about 0.5 to about 10). The combination of the one or more dielectric material layers, one or more semiconductor material layers, and the one or more metal material layers provides increased contrast in refractive index between layers, thereby increasing total internal reflectance, interference (resonance) effects, and directionality of light in the high index materials (e.g., a refractive index above about 3). Furthermore, the thickness of these layers may be adjusted or adapted to provide an increase in performance for a particular application.

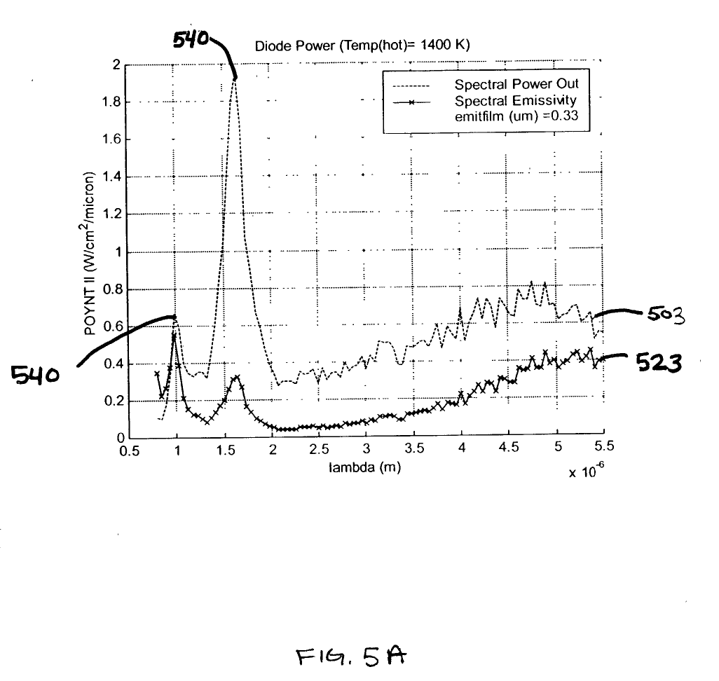

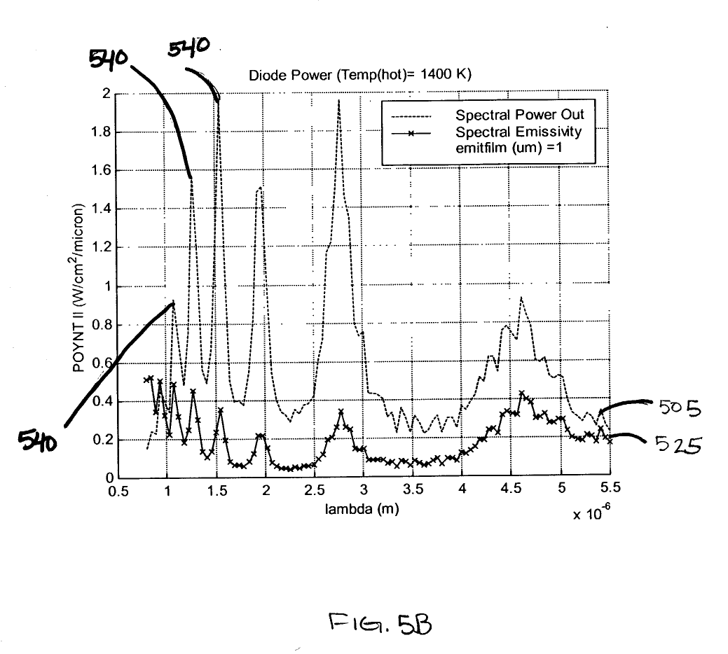

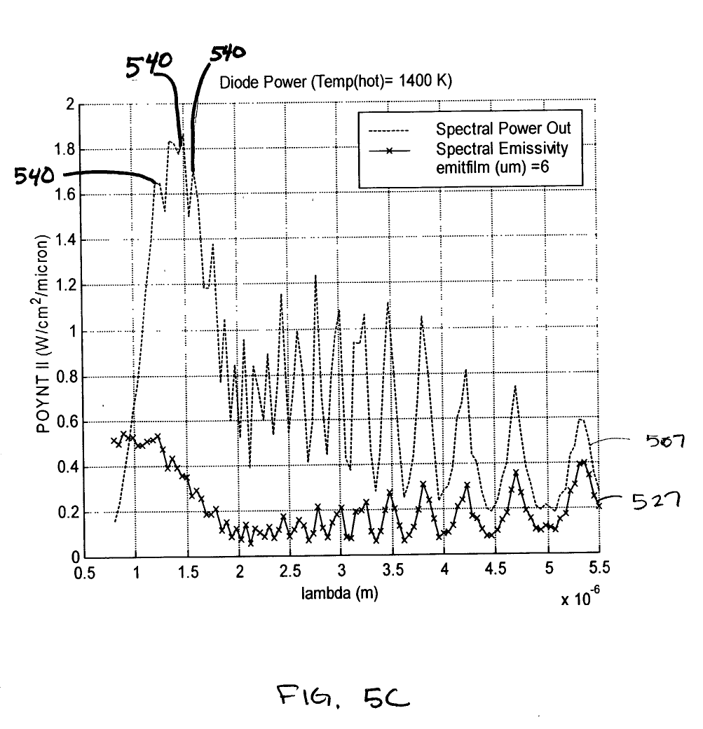

In addition to backing layers 22, an antireflective coating 24, such as shown in FIG. 4, may be added to improve emittance of photons within a specific wavelength range (e.g., between about 1.2 microns and about 1.5 microns). Illustratively, the antireflective coating 24 includes dielectric and semiconductor materials to reduce reflectance of the semiconductor layer 20, and thereby increase emissivity of photons, within the specified wavelength range. In some embodiments, the antireflective coating 24 is a single layer as shown in FIG. 4. In other embodiments, the antireflective coating 24 includes multilayers of dielectric and semiconductor materials. In addition to increasing the emissivity of the semiconductor layer 20, the antireflective coating 24 also protects the semiconductor layer from oxidation and reduces evaporation of semiconductor material when the semiconductor layer is heated.

Optimization of a TPV system is a multivariable problem that is dependent upon one or more goals of a particular application of a particular TPV system. The selectivity ratio (the average emissivity in the wavelength region of interest divided by the average emissivity outside the wavelength region of interest) and radiation efficiency (total emittance for wavelengths at or below the bandgap of the photovoltaic converter divided by the total emittance) of the selective emitter 15 described herein may be adjusted to suit the requirements or to increase the performance of the particular application. In one embodiment, it is preferable to define the selectivity ratio as the average emissivity in the wavelength region of about 1.5 microns divided by the average emissivity in the wavelength region of about 5 microns and the radiation efficiency as the total emittance for wavelengths of about 1.7 microns or less divided by the total emittance for wavelengths of about 5 microns or less. In another embodiment of the invention including for example a selective emitter 15 having a semiconductor layer 20 with a 0.5 eV bandgap and in thermal communication with a heat source 18 at 700 K, it is preferable to define the selectivity ratio as the average emissivity in the wavelength region of about 2.2 microns divided by the average emissivity in the wavelength region of about 5 microns and the radiation efficiency as the total emittance for wavelengths of 2.5 microns or less divided by the total emittance for wavelengths of 30 microns or less.

To adjust or alter the selectivity ratio and radiation efficiency of the selective emitter, the material properties and/or the thickness of each of the semiconductor layer 20, the backing layer 22, and the antireflective coating 24 may be varied. The following sections describe a number of illustrative embodiments according to the invention to highlight how material properties and the thickness of each layer (semiconductor layer 20, backing layer 22, and antireflective coating 24) effects the selectivity ratio and radiation efficiency of the selective emitter. The description in the following sections is by no means an exhaustive list of the possible embodiments of the invention, but is included to illustrate some of the ways each layer may be tailored to effect the selectivity ratio and radiation efficiency.

Semiconductor Layer

Semiconductor material selection of the semiconductor layer influences the radiation efficiency of the TPV system. As discussed above, optimization of a particular TPV system depends upon the particular TPV application. Thus, to increase efficiency of the TPV system, it is important to adjust the selective emitter such that the emitted light spectra are efficiently converted within the TPV system.

In one illustrative embodiment, an indirect bandgap semiconductor material, such as, for example silicon or germanium, is used as the semiconductor material forming the semiconductor layer 20. Common indirect bandgap semiconductor materials are inexpensive as compared to direct-bandgap materials, and are substantially stable at elevated temperatures (e.g., about 1400 K). Accordingly, in some embodiments of the invention, it is preferred that the selective emitter includes a semiconductor layer having an indirect bandgap semiconductor material.

In another illustrative embodiment of the invention, it is preferred that the semiconductor layer 20 includes a thin layer of undoped, direct bandgap, semiconductor material, such as indium gallium arsenide or gallium arsenide. Because of the direct bandgap and the thin (for example, less than about 100 microns; preferably less than about 10 microns) semiconductor layer 20, the emittance spectrum is a band consisting primarily of that portion of the blackbody spectrum above the bandgap energy (e.g., above about 0.75 eV). The portion of the blackbody spectrum below the bandgap is radiated from thermally-excited free carries and from transitions between valance-band levels emptied by electron excitation into the conduction band.

A direct bandgap semiconductor material has a very high absorption coefficient (e.g., above about 10⁴/cm, within about 50 mV above the bandedge), usually up to ten times that of indirect bandgap materials (e.g., absorption coefficient of less than about 10³/cm, within about 50 mV above the bandedge). This high absorption coefficient translates into high broadband emittance above the bandgap energy. Thus, the semiconductor layer 20 having a thickness less than about 100 microns reduces the free-carrier emission of the unusable long-wavelength light (e.g., wavelength greater than about 1.5 microns). As a consequence, it is the metallic layer 21 of the backing layer 22 that controls the long wavelength light emission, not the semiconductor layer 20. Thus, the background or out-of-band emissivity may be reduced by an order of magnitude, for example 0.03 versus 0.25, relative to that of conventional selective emitters having a thickness much greater than 100 microns.

It is preferred that the direct bandgap semiconductor material be undoped to reduce the number of free carriers available for emission. The photovoltaic converter 8 may also be made from an essentially updoped material. For example, its contacts may be made closely-spaced and physically small (e.g., arrays of externally-connected point, collectors that are each less than about 5 microns across). With 100 microns spacing, the internally-connecting n+ and p+ conductive layers may be made thin (e.g., less than about 100 nanometers) to reduce free-carrier collection of non-useful light in these regions. In other embodiments, such as an embodiment including a specific filter that reflects back peaks of non-usable light emitted from the selective emitter 15, the TPV system can be tuned to complement the selective emitter 15 for improved TPV system 1 efficiency.

Below is described a model for how thickness of the semiconductor layer 20 effects emissivity (ε). This model includes the following terms: refractive index (n), extinction coefficient (k), reflectivity (R), transmissivity (T), and absorptivity (α). The general equation for emissivity is:

ε=(1−R)(1−T)/(1−R*T) Eq. (1),

R=[(n−1)2+k2]/[(n+1)2+k2] Eq. (2).

When a material thickness (t) is opaque to the wavelength of interest (T=0), the emissivity equation reduces to:

ε=(1−R)=4nk/[(n+1)2+k2] Eq. (3).

When the material thickness (t) is thin so as to be nearly transparent to the wavelength of interest, the emissivity equation reduces to:

ε=4πk t/λ˜αt Eq. (4).

The actual emissivity is the emissivity of the semiconductor layer 20 plus that of the heat source 18 and/or the backing layer 22 behind the semiconductor layer 20. The semiconductor layer 20 is preferably nearly transparent to the wavelength of interest, whereas the heat source 18 is preferably opaque to the wavelength (T=0) and the backing layer 22 should be highly-reflective (metallic, k>>n, thus R is about 1 in equation 2) beyond the wavelength of interest. If the backing layer 22 includes a dielectric backing layer 23 between the metal backing layer 21 and semiconductor layer 20, the dielectric backing layer 23 will have a high transmission (T=1) and therefore a low emittance (see equation 1). The resulting actual emissivity is thus defined as:

ε=α_{(semiconductor)}t_{(semiconductor)}+ε₍ₘₑₜₐₗ₎ Eq. (5),

ε=α_{(semiconductor)}t_{(semiconductor)}+4n₍ₘₑₜₐₗ₎k₍ₘₑₜₐₗ₎/[(n₍ₘₑₜₐₗ₎+1)2+k₍ₘₑₜₐₗ₎2] Eq. (6).

The total emissivity for long wavelength light is near that of the metal backing layer 21 if α_{(semiconductor)}t_{(semiconductor)}<4n₍ₘₑₜₐₗ₎k₍ₘₑₜₐₗ₎. Within the free carrier region, the absorptivity of the semiconductor layer (α_{semiconductor}) increases dramatically with increasing temperature. For example, absorptivity of a direct bandgap semiconductor at 1000K is greater than about 100/cm. Thus, the thickness of the semiconductor layer 20 is preferably less than about 100 microns, and in one embodiment, equal to or less than about 1 microns to guarantee that α_{(semiconductor)}t_{(semiconductor)}<4n₍ₘₑₜₐₗ₎/k₍ₘₑₜₐₗ₎. However, the conductivity (σ=n k/30λ) of the metallic layer decreases with temperature. Since n does not change much with temperature, k is seen to also decrease with temperature and the emittance of the metallic backing layer 21 will therefore increase with temperature. Thus, the metallic backing layer 21 becomes a limiting factor in trying to reduce emission of unusable long-wavelength light.

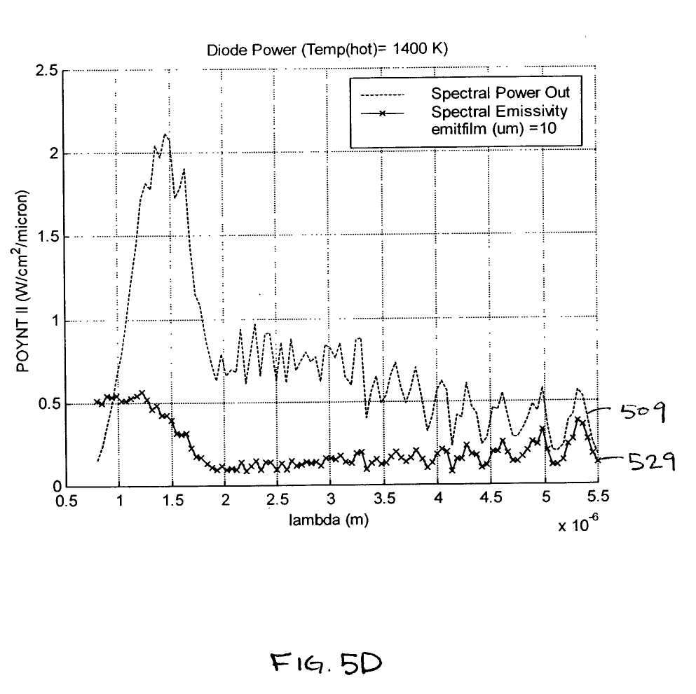

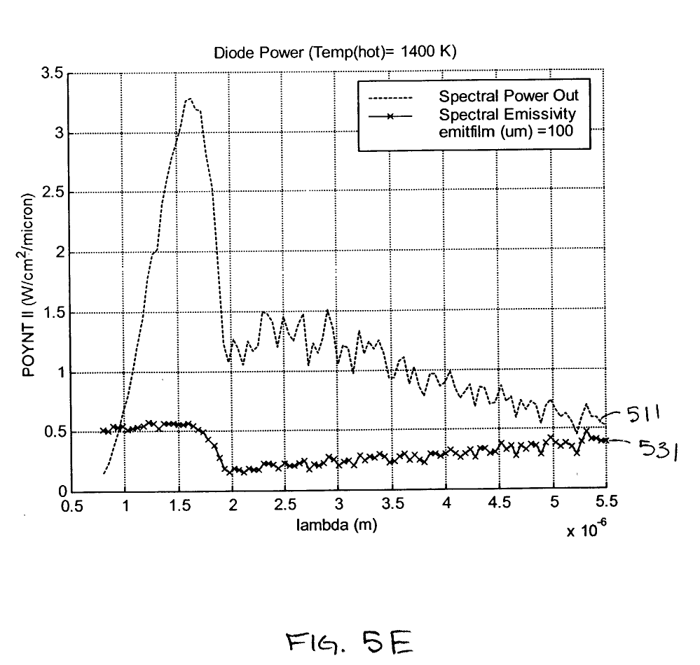

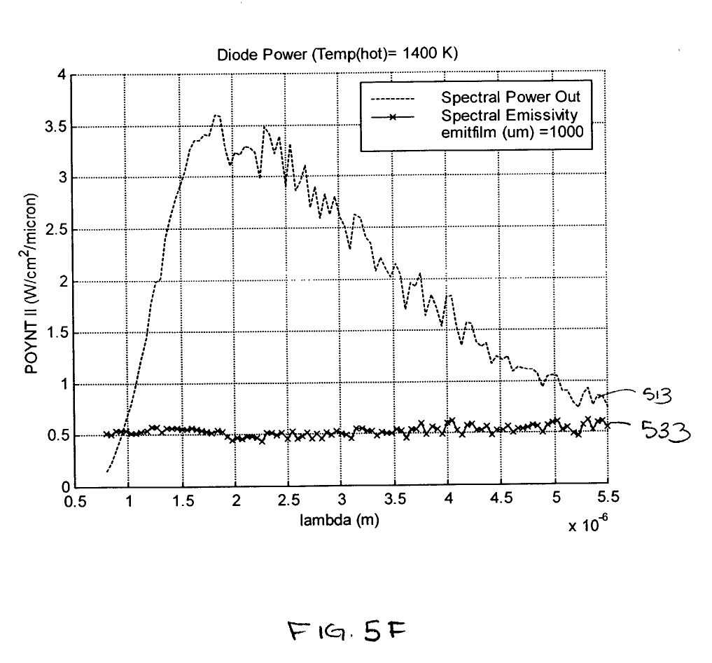

The thickness of the semiconductor layer 20 also influences the radiation efficiency of the TPV system. FIGS. 5A-5F show graphs of emittance (spectral power output) and emissivity versus wavelength for various illustrative embodiments of the selective emitter 15 having a tantalum metallic backing layer 21 in thermal communication with a heat source 18 at 1400 K, and various thicknesses of a pure silicon semiconductor layer. Specifically, curves 503, 505, 507, 509, 511, and 513 in FIGS. 5A-5F, show simulated spectral power output data for silicon semiconductor layers having thicknesses of, respectively, 0.33 microns,, 1 micron, 6 microns, 10 microns, 100 microns, and 1000 microns. Curves 523, 525, 527, 529, 531, and 533 show simulated emissivity data (unitless, and with a maximum value of 1) for silicon semiconductor layers having thickness of, respectively, 0.33 microns, 1 micron, 6 microns, 10 microns, 100 microns, and 1000 microns. The y-axis of FIGS. 5A-5F displays theoretical or modeled spectral power output as the Poynting vector having units of Watts/cm²/micron. Thus, a comparison of curves 503, 505, 507, 509, 511, and 513 illustrates the effects of thickness of the semiconductor layer 20 on emittance of the selective emitter 15.

As shown in FIGS. 5D-5F, as the thickness of the semiconductor layer 20 decreases from 1000 microns to 10 microns, so does the emittance at a particular wavelength. For example, curve 513 shows an emittance value of 3 watts/cm²/micron at a wavelength of 1.5 microns, whereas curve 509 shows an emittance value of about 2.1 watts/cm2/micron at a wavelength of 1.5 microns. However, while the emittance value at a particular wavelength drops with decreasing thickness values of the semiconductor layer 20, the emittance within the preferred wavelength range (e.g., the total emittance for wavelengths of 1.7 microns or less) compared to the emittance from the total spectrum (e.g., the total emittance for wavelengths of 5 microns or less), actually increases with decreasing thickness of the semiconductor layer 20. For example, radiation efficiency defined as the ratio of emittance within the preferred wavelength range to the emittance of the total spectrum increases from 18.5% for the semiconductor layer 20 having a thickness of about 1000 microns, curve 513, to 36.5% for the semiconductor layer 20 having a thickness of about 10 micron, curve 509.

Referring to FIG. 5A-5C, The number of peaks 540 in the spectral power output data for silicon semiconductor layer thicknesses of 6 microns and below arises due to interference effects generated by the actual thickness of the semiconductor layer 20. The radiation efficiency actually decreases from 34% for the 6 microns thick silicon semiconductor layer of FIG. 5C to 24% for the 1 micron thick silicon semiconductor layer of FIG. 5B. However, as the number of peaks 540 decreases, it becomes possible to match the emission peaks 540 to a particular photovoltaic converter 8 of a particular TPV system 1. Thus, the radiation efficiency increases from 24% for the 1 micron semiconductor layer of FIG. 5B to 25% for the 0.33 micron semiconductor layer of FIG. 5A. Accordingly, in some embodiments of the invention, a preferred thickness of the silicon semiconductor layer 20 is less than about 0.5 microns.

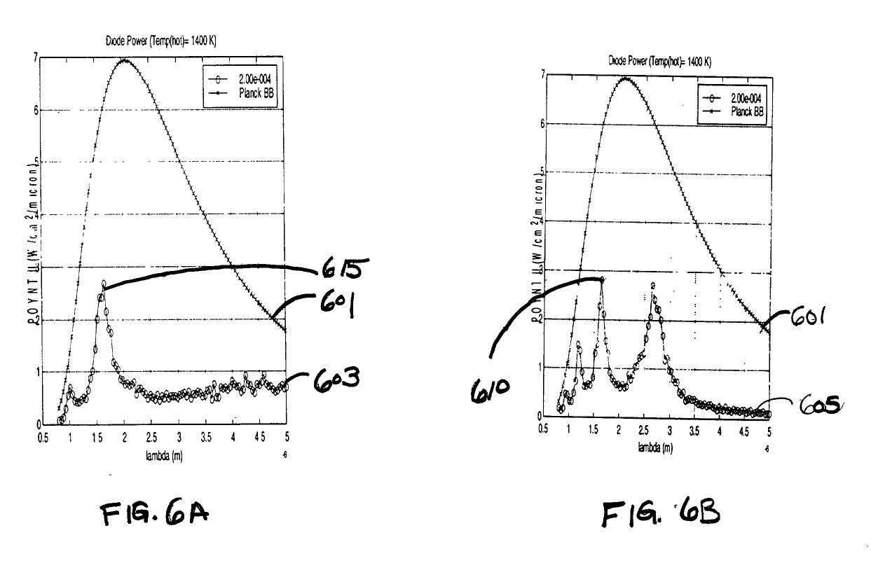

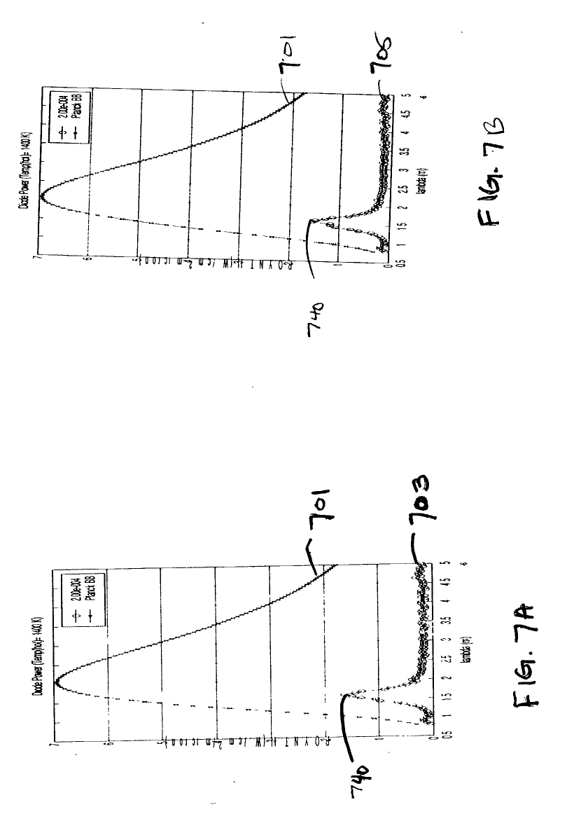

Other TPV systems are more efficient when the peaks present in the spectrum are narrow (e.g., have a single sharp peak having a bandwidth of about 0.1 microns). If extra, unwanted peaks can be removed from the spectra, such as for example through the use of an internal or external filter, a selective emitter with a silicon semiconductor layer 20 having a thickness of about 0.5 microns to about 10 microns is preferred. FIGS. 6A-6B show graphs of emittance versus wavelength (simulated performance curves 603, 605) for, respectively, a selective emitter 15 including a silicon semiconductor layer 20 having a thickness of about 0.09 microns, and a selective emitter including a silicon semiconductor layer 20 having a thickness of about 0.6 microns. Both embodiments of the selective emitter 15 include a highly-conductive (e.g., greater than about 10⁶/ohm-m) and optically opaque backing layer 22. As shown in FIGS. 6A-6B, a peak 610 at a wavelength about 1.5 microns of curve 605 is much sharper than a similar peak 615 of curve 603. Thus, in an embodiment of the invention that includes a filter to suppress unwanted peaks, a silicon semiconductor layer 20 of a thickness about 0.2 microns to about 1 micron is preferred.

Material properties such as, for example, refractive index and conductivity, can effect both emittance and the selectivity ratio of the emitter. FIGS. 7A-7B show graphs of emittance versus wavelength (simulated performance curves 703, 705) for, respectively, a neutral-spectral-density emitter (a theoretical material emitter with no wavelength dependence in refractive index, conductivity, or absorption) and for a selective emitter 15 including a pure silicon semiconductor layer. Both the neutral-spectral-density emitter and the selective emitter including the silicon semiconductor layer 20 have a thickness of about 0.1 microns and both emitters also include a backing layer 22 including a dielectric layer and a highly conductive layer in thermal communication with a heat source at 1400 K. For reference, FIGS. 7A-7B also include a curve 701 showing emittance versus wavelength for a Planck blackbody at 1400 K.

A comparison of the simulated performance curves 703 and 705 illustrates the effects of selecting a material with a relatively high differential conductivity (e.g., a decrease in conductivity of about 10 times between λ=1 microns and λ=2 microns, from greater than about 10³/ohm-m to about less than 10 ohm-m, respectively). For example, the simulated performance curves 703, 705 show that both emitters (neutral-spectral-density emitter having a neutral material thickness of about 0.1 microns, and the selective emitter 15 having a semiconductor layer 20 with a thickness of about 0.1 microns) have a single peak at about 1.6 microns with a Poynting vector value of about 1.5 Watts/cm2/micron. However, the emitter including the silicon semiconductor layer 20 with a higher differential conductivity has a lower total emittance beyond a wavelength of 2.5 microns. As shown, in FIGS. 7A and 7B, curve 705 has an average emittance of about 0.1 Watts/cm2/micron beyond a wavelength of 2.5 microns, whereas curve 703 has an average emittance of about 0.2 Watts/cm2/micron beyond a wavelength of 2.5 microns. Thus, the emitter 15 with the substantially higher differential conductivity reduces the spectral output power beyond a wavelength of 2.5 by about 50%, thereby producing a significant increase in the radiation efficiency (ratio of emittance within the preferred wavelength range to the emittance of the total spectrum). For example, the radiation efficiency calculated from curve 705 is 45%, whereas the efficiency calculated from curve 703 is 33%. Furthermore, the selectivity ratio (the average emissivity in the wavelength region of about 1.5 microns divided by the average emissivity in the wavelength region of about 5 microns) for the selective emitter 15 including the silicon semiconductor layer 20 is about 8, while the neutral-spectral-density emitter's selectivity ratio is about 4. Accordingly, in one embodiment of the invention, a selective emitter 15 having a semiconductor layer 20 made from a material having relatively high differential conductivity is desirable for a TPV application requiring a selective emitter with both a relatively high selectivity ratio (e.g., greater than or equal to about 6) and radiation efficiency (e.g., greater than about 33%).

The sharp peaks 740 shown in FIGS. 7A-7B are desirable for increased conversion efficiency of heat to electrical energy. The sharpness of the peaks 740 arises due to differences in refractive indices between the semiconductor layer 20, the backing layer 22, and the antireflective coating 24. Accordingly, in one embodiment of the invention, it is preferable to include layers of dielectric materials (having a refractive index of less than about 1.5), semiconductor materials (having a refractive index of about 3 to about 4), and metal materials (having a refractive index of about 0.5 to about 10) to obtain significant differences (e.g., changes of at least about 1) in refractive index between the layers.

Absorption properties of the semiconductor layer can also effect the efficiency of the TPV 1 system. Generally, absorption properties are dominated by interference effects when the semiconductor layer 20 is significantly thinner (e.g., at least about 10 times less) than the extinction depth of the semiconductor layer (e.g., for a silicon semiconductor, absorption properties have little effect on semiconductor layers less than about 0.5 microns thick). However, for thicker silicon semiconductor layers, absorption properties affect the efficiency by reducing the emittance beyond the wavelength region of interest (e.g., beyond 1.5 microns).

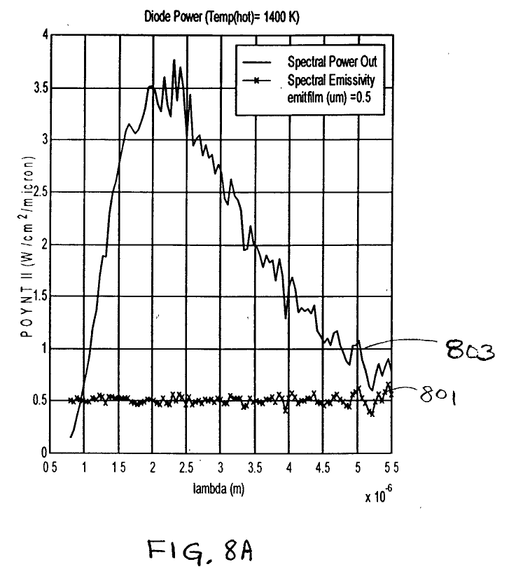

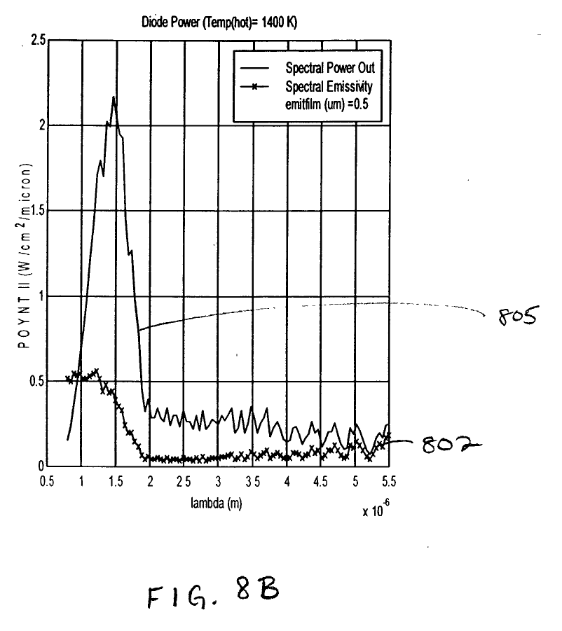

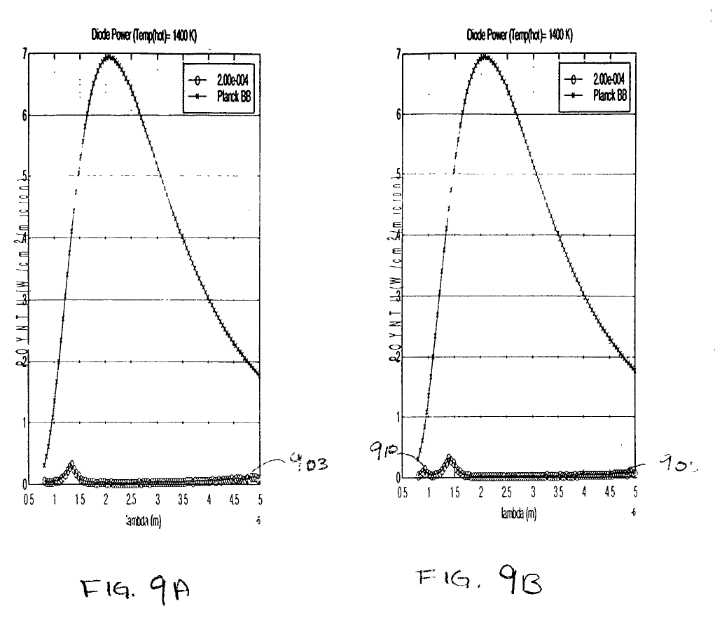

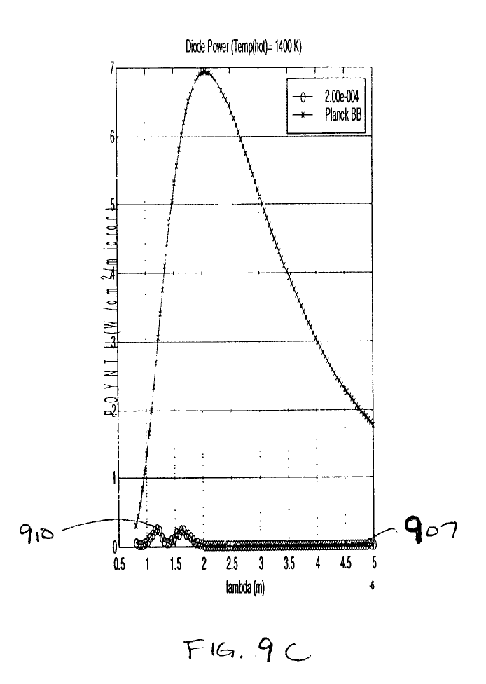

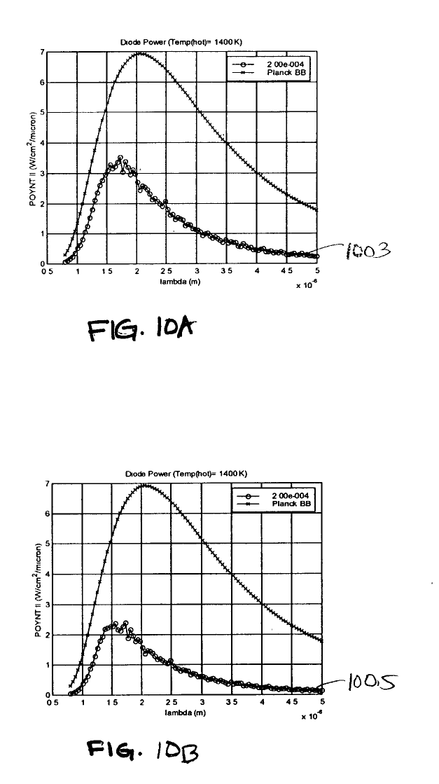

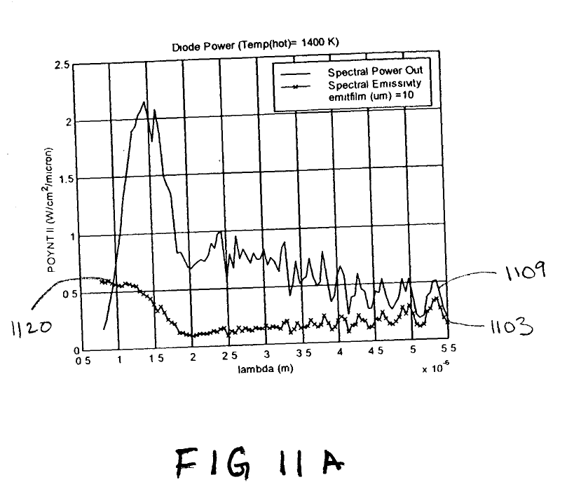

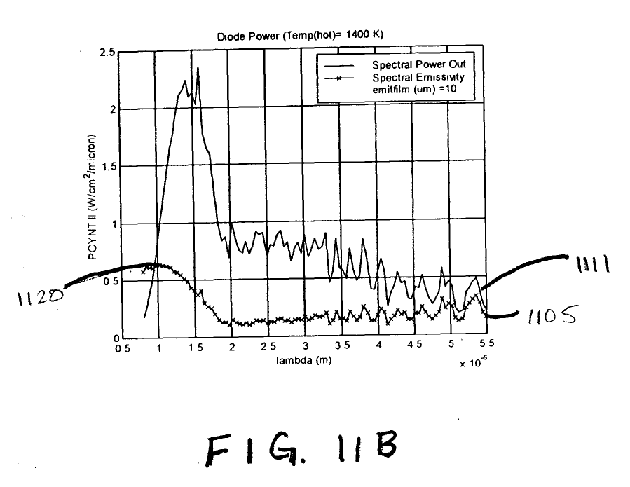

FIGS. 8A-8B show graphs of emittance versus wavelength for, respectively, a neutral-spectral-density emitter 15 having a thickness of about 10 microns, and a selective emitter 15 including a silicon semiconductor layer 20 having a thickness also about 10 microns. Each of the emitters (neutral-spectral density and the selective) has an optically-opaque and highly conductive tantalum backing layer 21 and is in thermal communication with a heat source 18 at 1400 K. Also each emitter has a 0.6 micron thick dielectric backing layer 23.

FIGS. 8A shows that the neutral-spectral-density emitter has a substantially flat spectral emissivity curve 801, and thus the neutral-spectral-density emitter has substantially no selectivity. FIG. 8B shows that the 10 silicon semiconductor layer selective emitter has a spectral emissivity curve 802 having a significant decrease (e.g., about 0.5 Watts/cm2/micron to about 0.1 Watts/cm2/micron) in spectral emissivity between a wavelength of about 1.5 microns and a wavelength of about 2 microns. The decrease in the spectral emissivity curve indicates that the 10 micron silicon semiconductor layer 20 is a selective emitter in the wavelength region of interest (e.g., about 1.2 microns to about 1.7 microns) and, as such, suppresses emission of photons having a wavelength beyond 1.7 microns.

A comparison of simulated performance curves of spectral power output for the neutral spectral-density material and the silicon semiconductor layer 803, 805 illustrates absorption effects for materials with an absorption dependence on wavelength. Curve 805 shows a reduction in emittance beyond 1.6 microns (e.g., beyond the wavelength region of interest). Calculations of efficiency from the simulated performance curves 803, 805 indicate that the efficiency increases from 18% for the neutral-spectral-density emitter to 51% for the selective emitter 15 having a silicon semiconductor layer 20 about 10 microns thick. Accordingly, in some embodiments, a selective emitter 15 having a semiconductor layer 20 with a thickness of about 0.5 microns to about 10 microns and an absorption coefficient highly dependent on wavelength is preferred.

Backing Layer

The radiation efficiency of the selective emitter 15 may also be adjusted to suit a particular TPV application by, for example, altering the thickness and material properties of the backing layer 22.

FIGS. 9A-9C show graphs of emittance versus wavelength for various embodiments of the selective emitter 15 at 1400 K and including a silicon semiconductor layer 20 having a thickness of 0.2 micron and various thicknesses of a dielectric backing layer. Specifically, curves 903, 905, and 907 in FIGS. 9A-9C show simulated performance data for selective emitters 15 having dielectric backing layer 22 including thickness of, respectively, 0.2 microns, 0.4 microns, and 0.6 microns.

FIGS. 9A-9C indicate a thin-layer effect by the reduction of the double peak as the backing layer 22 thickness decrease from 0.6 microns to 0.4 microns to 0.2 microns. Specifically, graphs 9A-9C show that for a selective emitter 15 including a thin dielectric backing layer (e.g., the dielectric backing layer has a thickness significantly thinner, for example 10 times thinner, than the extinction depth of the dielectric material), the thickness of the backing layer 22 effects efficiency of the selective emitter 15.

For example, as the thickness of the dielectric backing layer is reduced from 0.6 microns to 0.4 microns to 0.2 microns a peak 910 corresponding to a wavelength of 1 micron in the curves 905, 907 decreases such that curve 903 does not include a peak at a wavelength of 1 micron. As discussed above, the wavelength range of interest is between about 1.2 microns and about 1.5 microns. Accordingly, much of the energy emitted from the 1 micron wavelength peak is lost during photovoltaic conversion. Thus, in some embodiments of the invention, efficiency of a TPV system 1 can be increased by selecting a thickness for the backing layer 22 that compliments interference effects for a thin semiconductor layer 20, thereby decreasing excess, unwanted peaks within the emitted spectrum of the selective emitter 15.

Altering the thickness, surface smoothness, and material properties, such as, for example density and conductivity, of the metallic backing layer 22 also influences the efficiency of the selective emitter 15. To minimize or suppress emittance from non-usable or non-suitable wavelength regions, a metal with a high spectral reflectance in the non-useable wavelength region is preferably used. The metallic backing layer's thickness and smoothness provide high reflection over a critical wavelength region defined as a wavelength of about 1 microns to a wavelength of about 30 microns. A plausible metallic material able to withstand high temperatures without diffusing into the semiconductor layer is tantalum. Tantalum, at room temperature, has a reflectivity between about 0.982 and 0.962 at an energy range between about 0.2 eV and about 0.7 eV. This energy range encompasses the majority of the unusable-wavelength region. Other metals, such as platinum or tungsten, or even a suicide may be used within the backing layer 22 to increase the efficiency of a particular TPV system. According to one embodiment of the invention, material density of the metallic layer 21 is increased to provide high conductivity and reflectance. However, reflectivity is not the only influential property of the metallic layer 21. Other material properties, such as, for example, thickness and conductivity are also important in increasing the efficiency of the selective emitter 15 for a particular TPV application.

Since the optical thickness of the layers of the selective emitter is influential in increasing efficiency of the selective emitter 15 for a particular TPV system 1, it should be understood that the material properties of each layer can effect the optimal optical thicknesses of each of the semiconductor layer 20, backing layer 22, and antireflective coating 24. Since the metallic backing layer 21 should be optically opaque, its thickness variation should have no effect. However, since the metallic layer 21 has a skin depth, its material properties can be tailored to provide an additional interference layer.

Conductivity of the metallic backing layer 22 also influences the efficiency of the selective emitter 15. FIGS. 10A-10B show graphs of emittance versus wavelength for various embodiments of the selective emitters 15 including a silicon semiconductor layer having a thickness of about 0.1 microns and various optically opaque and conductive metallic backing layer 21. Specifically, curves 1003, 1005 in FIGS. 10A-10B, show simulated performance data for metallic backing layers 21 having a conductivity of, respectively, 2×10⁶/ohm-meters, and 9×10⁶/ohm-meters.

As shown in FIGS. 10A-10B, the emittance decreases with increasing conductivity. However, the selective emitter 15 having a higher conductivity, FIG. 10B, has lost more emittance in the region of non-suitable wavelength (e.g., wavelengths greater than about 1.5 microns), thereby increasing the efficiency of the selective emitter 15 having the higher conductivity. Accordingly, in some embodiments, a selective emitter 15 having a highly conductive backing layer (e.g., greater than or equal to about 9 ×10⁶/ohm-meters) is preferred.

Antireflective Coating

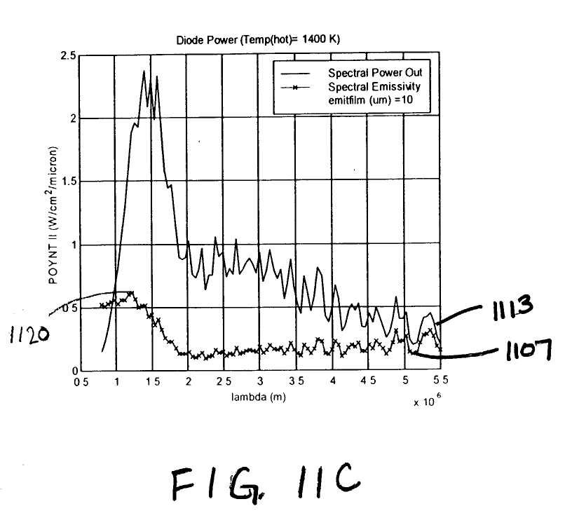

The thickness of the antireflective coating 24 can also influence the efficiency of the TPV system 1. For example, an antireflective coating 24 on the semiconductor layer 20 can lower the reflectance and thus increase the emissivity from a selected wavelength region. FIGS. 11A-11C show graphs of emissivity and spectral output power versus wavelength for various embodiments of the selective emitter including a silicon semiconductor layer 20 having a thickness of 0.2 microns and antireflective coatings having various thicknesses. Specifically, curves 1103, 1105, and 1107 graph simulated emissivity data from selective emitters 15 having antireflective coating 24 having thicknesses of, respectively, 0.1 microns, 0.2 microns, and 0.3 microns. Curves 1109, 1111, and 1113 graph simulated spectral power output data for the embodiments of FIGS. 11A, 11B, and 11C, respectively. While the radiation efficiency does not drastically change with increasing or decreasing thicknesses of the antireflective coating 24, FIGS. 11A-11C indicate that a first emissivity peak 1120 shifts to longer wavelengths (e.g., from about 1 micron in FIG. 11A, to about 1.1 micron in FIG. 11B, and to about 1.2 microns in FIGS. 11C) with increasing thickness of the antireflective coating. An increase in efficiency can be realized by selecting a thickness of the antireflective coating 24 that produces an emittance spectrum that substantially correlates with the photovoltaic converter 8 within the particular TPV system 1.

A further improvement to selective emitters according to this invention is to employ a composite layer 50 having a wide-bandgap material (e.g., above about 1 eV) surrounding a thin region (down to quantum well thicknesses) of a narrow-bandgap material (e.g., above out 0.5 eV). The composite layer 50 is preferably about 0.05 micron to 10 microns thick and therefore has substantially no free-carrier absorption or emittance at temperatures compatible with integrity and TPV system operation.

FIG. 12 shows an illustrative embodiment of a selective emitter 45 including a composite layer 50 in thermal contact with a heat source 48. The composite layer 50 includes a region of a wide-bandgap material, such as gallium arsenide, surrounding a thin region of a narrow-bandgap material, such as indium gallium arsenide. The region of wide-bandgap material surrounding the region of narrow-bandgap material forms at least one quantum well within the composite layer 50. While for the purposes of this example, the composite layer includes direct bandgap semiconductors, in other embodiments, indirect bandgap semiconductor materials such as silicon-germanium alloys, or metal materials are used within the composite layer 50.

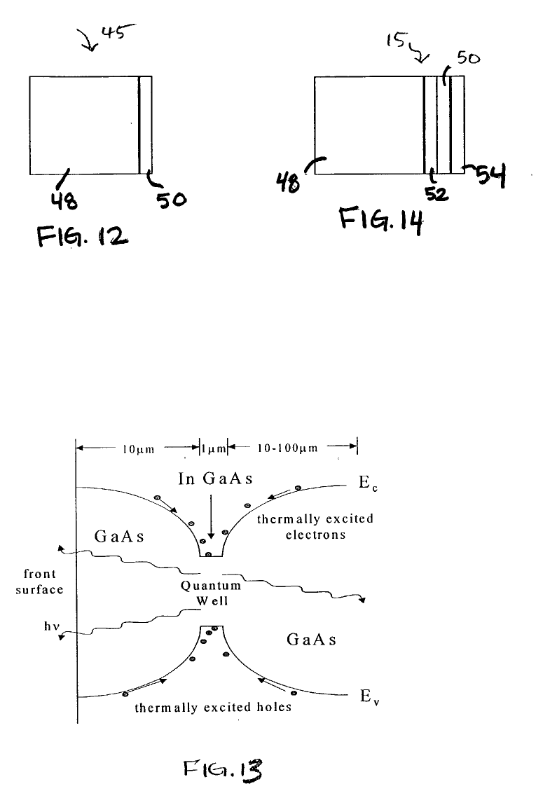

FIG. 13 depicts an illustrative example of the composite layer 50 including indium gallium arsenide (InGaAs) and gallium arsenide (GaAs, or more commonly InP or InAlAs, which wide bandgap materials can be lattice-matched to InGaAs). The composite layer 50 provides a high density of states (e.g., near bulk material levels) needed for high absorption coefficients (e.g., above about 10⁴/cm ) and for high emittance (within the ε=αt regime). In this embodiment of the composite layer 50, the high emittance extends over a broad wavelength band (e.g., above about 100 nanometers) rather than over narrow absorption edges characteristic of atomic spectra or point defects. The thin thickness (e.g., about 10 to about 200 nanometers) of the narrow-bandgap region (e.g., about 0.5 eV to about 0.75 eV) within the composite layer 50 reduces the free-carrier degrees of freedom and thus, the free carrier emission. If thinner narrow-bandgap regions (e.g., about 10 to 200 nanometers) are beneficial in terms of increasing conductivity (through creation of a two-dimensional, electron gas), then multiple layers of less than about 10 nanometers each (quantum wells) can be used within the composite layer 50.

Referring to FIG. 14, another embodiment of the selective emitter 50 includes both a backing layer 52 and an antireflective coating 54. It should be noted that the backing layer 52 may include a dielectric layer, a semiconductor layer, and a metallic layer and that either the backing layer 52 or the antireflective coating 54 may be removed depending upon optimization of the TPV system. In some embodiments, the antireflective coating includes a single layer of dielectric and/or semiconductor material. In other embodiments, the antireflective coating includes multiple layers of dielectric and/or semiconductor materials.

In an alternative embodiment, selective growth of the narrow-bandgap material region further suppresses free carrier emission by reducing the population of electrons in levels that can radiate. In another embodiment, the quantum well and or the wide-bandgap material may be optimized in several ways to increase the efficiency of the selective emitter and TPV system. For example, the thickness of the quantum well, as well as the composition and orientation of materials used may be altered to increase efficiency.

Holes and electrons, thermally generated within the wide-bandgap material within the composite layer 50 are swept into the quantum well by a built-in electric field before the electrons can emit from the wide-bandgap layers. Thus, these electrons contribute to the photon flux from the quantum well and not to the free-carrier wavelengths.

This steady-state, non-equilibrium condition raises the effective temperature of the quantum well by hundreds of degrees. Thus, the selective emitter 45 having a composite layer 50 is selective and produces a higher photon output at the selected wavelength range than other emitters at the same temperature. According to a further feature, the difference in flow rate of electrons and holes to the quantum well is self-equalizing. The balance of carriers swept into the well controls the Fermi level of the quantum well. The higher number of electrons and holes within the quantum well increases the recombination rate and the local emittance of the selective emitter 45.

The electrons may be constrained toward motion parallel to the surface. This constraint may improve the coupling between the emitter and the photovoltaic converter if the emitter and the converter are similar in structure.

The composite layer 50 may also provide anisotropic emission, such that fewer emitted photons are lost by total internal reflection at a surface of the selective emitter 50.

The higher effective temperature of the composite layer 50 can be enhanced by the use of properly doping the wide-bandgap material region. The efficiency of the selective emitter 45 may also be enhanced by the “giant-dipole” moment found in quantum well structures. Such an increase in dipole moment, increases the refractive index of the composite layer 50 and thus the conductivity. Such effects greatly increase the emittance from the composite layer and allows enables a much thinner composite layer 50 to be effective beyond expectation based on thickness and bulk properties alone.

While the invention has been particularly shown and described with reference to specific illustrated embodiments, it should be understood by skilled artisans that various changes in form and detail may be made therein without departing from the spirit and scope of the invention.

What is claimed is:

1. A selective emitter for a thermophotovoltaic system, the selective emitter comprising:
a heat source; and
a semiconductor layer in thermal communication with the heat source, the semiconductor layer having a thickness less than 100 microns.

2. The selective emitter of claim 1, wherein the semiconductor layer comprises at least one indirect bandgap semiconductor material.

3. The selective emitter of claim 2, wherein the at least one indirect bandgap semiconductor material comprises silicon.

4. The selective emitter of claim 2, wherein the at least one indirect bandgap semiconductor material comprises germanium.

5. The selective emitter of claim 2, wherein the at least one indirect bandgap semiconductor material comprises a silicon alloy.

6. The selective emitter of claim 2, wherein the at least one indirect bandgap semiconductor material comprises a germanium alloy.

7. The selective emitter of claim 1, wherein the semiconductor layer comprises a direct bandgap semiconductor material.

8. The selective emitter of claim 7, wherein the direct bandgap semiconductor material comprises indium gallium arsenide.

9. The selective emitter of claim 1, wherein the semiconductor layer is crystalline.

10. The selective emitter of claim 1, wherein the semiconductor layer is amorphous.

11. The selective emitter of claim 1, wherein the semiconductor layer comprises a multi-bandgap semiconductor material.

12. The selective emitter of claim 1, wherein the semiconductor layer comprises at least two different semiconductor materials with different bandgaps.

13. The selective emitter of claim 12, wherein the semiconductor layer is graded.

14. The selective emitter of claim 1, wherein the semiconductor layer is ungraded.

15. The selective emitter of claim 1, wherein the semiconductor layer is doped.

16. The selective emitter of claim 1, wherein the semiconductor layer is counter-doped.

17. The selective emitter of claim 1, wherein the semiconductor layer is differentially-doped.

18. The selective emitter of claim 1 further comprising an antireflective coating deposited on the semiconductor layer.

19. The selective emitter of claim 1 further comprising at least one backing layer located between the heat source and the semiconductor layer, wherein the at least one backing layer is configured to increase output of photons of a wavelength suitable for conversion into electric energy by a photovoltaic converter relative to output of photons of a non-suitable wavelength.

20. The selective emitter of claim 19, wherein the backing layer comprises a dielectric material.

21. The selective emitter of claim 19, wherein the backing layer comprises a metallic material.

22. The selective emitter of claim 19, wherein the backing layer comprises a combination of dielectric layers, semiconductor layers, and metallic layers.

23. A selective emitter for a thermophotovoltaic system, the selective emitter comprising:
a heat source; and
a composite layer in thermal communication with the heat source; the composite layer comprising at least one quantum-well for emitting photons and having a thickness less than about 10 microns.

24. The selective emitter of claim 23, wherein the at least one quantum-well exists within doped semiconductor materials.

25. The selective emitter of claim 23, wherein the at least one quantum-well is an oriented-crystal quantum-well.

26. The selective emitter of claim 23, wherein the at least one quantum-well is a non-planar quantum-well.

27. The selective emitter of claim 23, wherein the at least one quantum-well is a stressed quantum-well.

28. The selective emitter of claim 23, wherein the at least one quantum-well includes a metal confined within barriers formed by at least one of a metal material, semiconductor material, dielectric materials, air interface, and vacuum interface.

29. The selective emitter of claim 23, wherein the composite layer further comprises a semiconductor having a bandgap that is wider than a bandgap of the at least one quantum-well.

30. The selective emitter of claim 23, wherein the composite layer further comprises a dielectric material.

31. The selective emitter of claim 30, wherein the dielectric material is alumina.

32. The selective emitter of claim 23 further comprising an antireflective coating deposited on the composite layer.

33. The selective emitter of claim 23 further comprising at least one backing layer located between the heat source and the composite layer, wherein the at least one backing layer is configured to increase output of photons of a wavelength suitable for conversion into electric energy by a photovoltaic converter relative to output of photons of a non-suitable wavelength.

34. The selective emitter of claim 33, wherein the backing layer comprises a dielectric material.

35. The selective emitter of claim 33, wherein the backing layer comprises a metallic material.

36. The selective emitter of claim 33, wherein the backing layer comprises a combination of dielectric layers, semiconductor layers, and metallic layers.

37. A method of converting thermal energy into photons having a selected wavelength, the method comprising:
placing a semiconductor layer in thermal communication with a heat source, the semiconductor layer having a thickness less than about 100 microns.

38. The method of claim 37 further comprising:
optimizing emission of photons of the selected wavelength by depositing one or more backing films on the semiconductor layer in between the heat source and the semiconductor layer.

39. The method of claim 37 further comprising:
optimizing emission of photons of the selected wavelength by depositing an antireflective coating on the semiconductor layer.

40. A method of converting thermal energy into photons having a selected wavelength, the method comprising:
placing a composite layer in thermal communication with a heat source, the composite layer comprising at least one quantum-well for emitting photons, the composite layer having a thickness less than about 10 microns.

41. The method of claim 40 further comprising:
optimizing emission of photons of the selected wavelength by depositing one or more backing films on the composite layer in between the heat source and the semiconductor layer.

42. The method of claim 40 further comprising:
optimizing emission of photons of the selected wavelength by depositing an antireflective coating on the composite layer.
